(19) United States
(12) Patent Application Publication
(10) Pub. No.: US 2024/0102165 A1
(43) Pub. Date: Mar. 28, 2024

(54) GAS SUPPLIER PROCESSING APPARATUS, AND METHOD OF MANUFACTURING SEMICONDUCTOR DEVICE

(71) Applicant: Kokusai Electric Corporation, Tokyo (JP)

(72) Inventor: Shuhei Saido, Toyama-shi (JP)

(73) Assignee: Kojusai Electric Corporation, Tokyo (JP)

(21) Appl. No.: 18/465,537

(22) Filed: Sep. 12, 2023

(30) Foreign Application Priority Data
Sep. 28, 2022 (JP) 2022-155532

(51) Int. Cl. C23C 16/455; C23C 16/52; H01L 21/67

(52) U.S. Cl. CPC C23C 16/45578; C23C 16/52; H01L 21/67017

(57) ABSTRACT

A technique includes a gas supplier including a first pipe into which a gas is introduced and a second pipe including an opening from which the gas is released, in which a flow path cross-sectional area of the second pipe is larger than a flow path cross-sectional area of the first pipe, and a direction in which the gas is released from the opening is inclined with respect to a direction from a center of the first pipe toward a center of the second pipe in a plan view.

### CROSS-REFERENCE TO RELATED APPLICATION

This application is based upon and claims the benefit of priority from Japanese Patent Application No. 2022-155532, filed on Sep. 28, 2022, the entire contents of which are incorporated herein by reference.

### FIELD

The present disclosure relates to a gas supplier, a processing apparatus, and a method of manufacturing a semiconductor device.

### DESCRIPTION OF THE RELATED ART

As one of the processes of manufacturing a semiconductor device, processing may be performed in which a film is formed on a substrate. A process performance is secured by causing a process gas to uniformly flow on a substrate by nozzles (hereinafter, each referred to as a gas supplier). In general, the gas supplier of this type is required to secure a space for installation.

### SUMMARY

The present disclosure provides a technique for achieving space saving of a gas supplier while securing characteristics of a gas supplied from openings.

According to some embodiments of the present disclosure,
there is provided a technique that includes a first pipe into which a gas is introduced and a second pipe including an opening from which the gas is released, in which a flow path cross-sectional area of the second pipe is larger than a flow path cross-sectional area of the first pipe, and a direction in which the gas is released from the opening is inclined with respect to a direction from a center of the first pipe toward a center of the second pipe in a plan view.

### BRIEF DESCRIPTION OF THE DRAWINGS

FIG. 1 is a longitudinal cross-sectional view schematically illustrating an example of a processing apparatus suitably used in some embodiments of the present disclosure.

FIG. 2 is an external view of a gas supplier provided in the processing apparatus suitably used in some embodiments of the present disclosure.

FIG. 3 is an external view of the gas supplier provided in the processing apparatus suitably used in some embodiments of the present disclosure.

FIG. 4 is a view illustrating an example of a cross-sectional view taken along line IV-IV in FIG. 3, wherein an illustration of an opening is omitted.

FIG. 5 is a view schematically illustrating a flow of a gas inside the gas supplier provided in the processing apparatus suitably used in some embodiments of the present disclosure, wherein an illustration of a coupler is omitted.

FIG. 6 is a view illustrating an example of a cross-sectional view of FIG. 3.

FIG. 7 is a view schematically illustrating a planar cross section of the processing apparatus suitably used in some embodiments of the present disclosure.

FIG. 8 is a view schematically illustrating an arrangement in a case where an additional gas supplier is provided in addition to the gas supplier provided in the processing apparatus suitably used in some embodiments of the present disclosure.

FIG. 9 is a view schematically illustrating an arrangement in a case where a second gas supplier is provided in addition to the gas supplier provided in the processing apparatus suitably used in some embodiments of the present disclosure.

FIG. 10 is a schematic configuration view of a controller used in the processing apparatus suitably used in some embodiments of the present disclosure, and is a block diagram illustrating a control system of the controller.

FIG. 11A is a graph illustrating a flow velocity of a source gas in a first pipe of the gas supplier.

FIG. 11B is a graph illustrating a concentration of a pyrolysis gas in the first pipe of the gas supplier.

FIG. 11C is a graph illustrating a partial pressure of the pyrolysis gas in a second pipe of the gas supplier.

FIG. 12 is a graph illustrating the flow velocity of a gas at openings formed in the second pipe of the gas supplier provided in the processing apparatus suitably used in some embodiments of the present disclosure.

### DETAILED DESCRIPTION

### Embodiments of the Present Disclosure

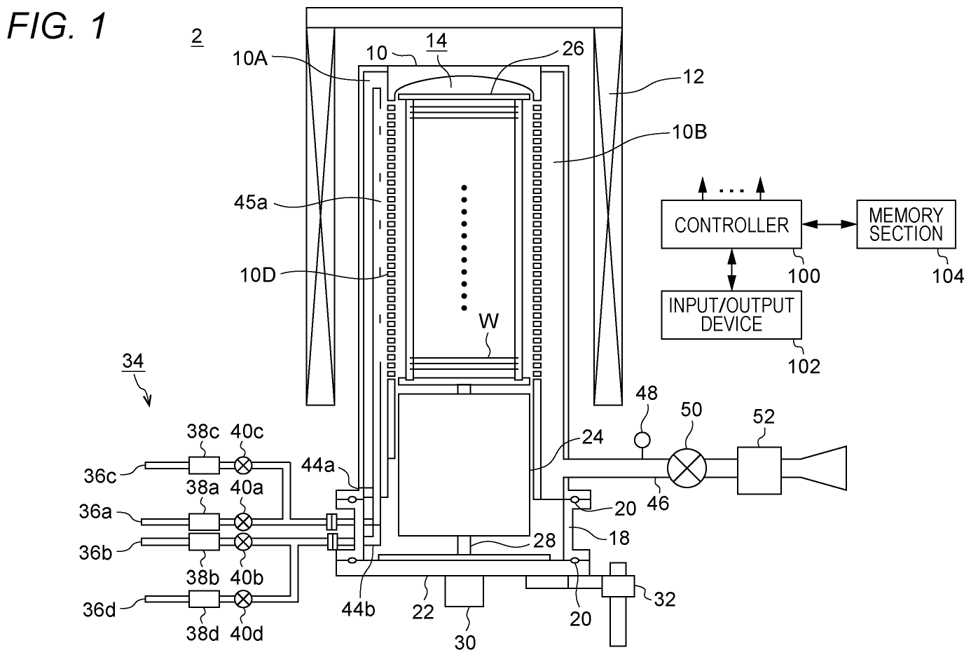

Some embodiments of the present disclosure will be described below mainly with reference to FIGS. 1 to 12. Furthermore, the drawings used in the following description are all schematic, and thus, dimensional relationships between constituent elements, ratios between constituent elements, and the like illustrated in the drawings do not necessarily coincide with realities. In addition, a plurality of drawings do not necessarily coincide with one another in dimensional relationships between constituent elements, ratios between constituent elements, and the like. Moreover, the reference numerals given in common in the drawings indicate the same member or structure even if there is no particular description in the description of the drawings.

(Processing Apparatus)

FIG. 1 is a longitudinal cross-sectional view schematically illustrating an example of a processing apparatus 2 in some embodiments. As illustrated in FIG. 1, a cylindrical manifold 18 is coupled to a lower end opening of a reaction tube 10 with a seal member 20 such as an O-ring interposed therebetween, and supports the lower end of the reaction tube 10. The manifold 18 is made of metal such as stainless steel, for example. A lower end opening of the manifold 18 is opened and closed by a disk-shaped lid 22. The lid 22 is made of metal, for example. A seal member 20 such as an O-ring is installed on an upper surface of the lid 22, whereby the inside of the reaction tube 10 is hermetically sealed from the outside air. A heat insulator 24 in which a hole is formed vertically at the center is mounted on the lid 22. The heat insulator 24 is made of quartz, for example.

A process chamber 14 houses, inside thereof, a boat 26 serving as a substrate holder that vertically supports a plurality of, for example, 25 to 150 wafers W to be processed, in a shelf-like manner. The boat 26 is made of quartz or SiC, for example. The boat 26 is supported above the heat insulator 24 by a rotation shaft 28 that penetrates the lid 22 and the heat insulator 24. The rotation shaft 28 is connected to a rotator 30 installed below the lid 22. Here, for example, a magnetic fluid seal is provided at a portion of the lid 22 through which the rotation shaft 28 penetrates. As a result, the rotation shaft 28 is formed rotatable in a state where the inside of the reaction tube 10 is hermetically sealed. The lid 22 is driven in a vertical direction by a boat elevator 32 serving as an elevator mechanism. As a result, the boat 26 and the lid 22 are integrally raised or lowered, and the boat 26 is loaded to and unloaded from the reaction tube 10.

The processing apparatus 2 includes a gas supply mechanism 34 that supplies a gas used for substrate processing into the process chamber 14. The gas supplied by the gas supply mechanism 34 is changed depending on a type of a film obtained by film forming processing. Here, the gas supply mechanism 34 includes a source gas supply system, a reactant gas supply system, and an inert gas supply system.

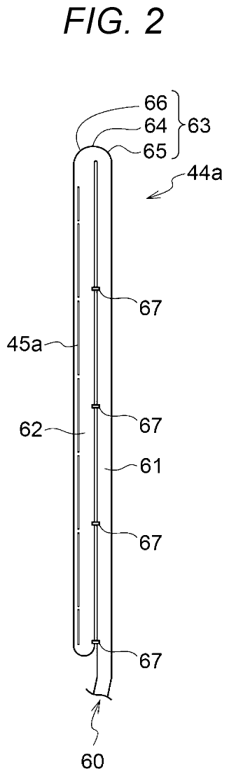

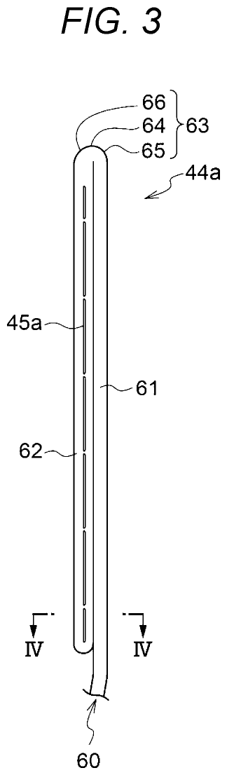

The source gas supply system includes a gas supply pipe 36a, and the gas supply pipe 36a is provided with a mass flow controller (MFC) 38a serving as a flow rate controller and a valve 40a serving as an opening/closing valve in this order from an upstream direction. The gas supply pipe 36a is connected to a gas supplier 44a penetrating a side wall of the manifold 18. The gas supplier 44a is formed as a nozzle as illustrated in FIGS. 2 and 3. The gas supplier 44a is provided upright inside a supply buffer chamber 10A along the vertical direction. A plurality of openings 45a each formed in a vertically long slit shape and opened toward wafers W held by the boat 26 are formed in the gas supplier 44a. A source gas is diffused into the supply buffer chamber 10A through the openings 45a of the gas supplier 44a, and the source gas is supplied to the wafers W through slits 10D of the supply buffer chamber 10A. Details of the gas supplier 44a will be described later.

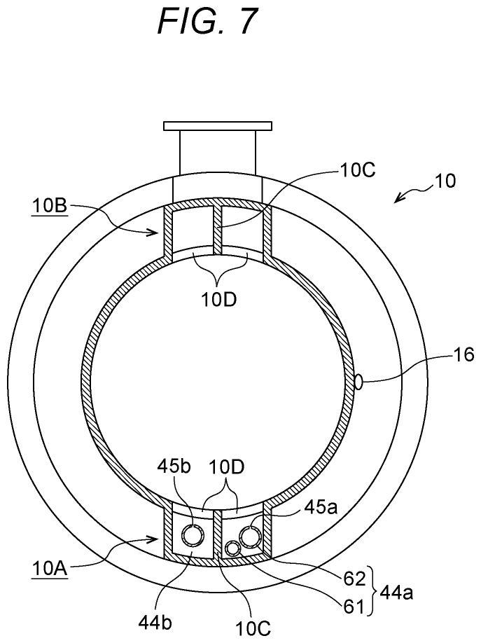

In the following, with a similar configuration, a reactant gas is supplied to the wafers W from the reactant gas supply system through a gas supply pipe 36b, an MFC 38b, a valve 40b, an additional gas supplier 44b, and the slits 10D. The additional gas supplier 44b is formed as a nozzle similarly to the gas supplier 44a. A plurality of openings 45b (see FIG. 7) opened toward the wafers W held by the boat 26 are formed in the additional gas supplier 44b. An inert gas is supplied to the wafers W from the inert gas supply system through gas supply pipes 36c and 36d, MFCs 38c and 38d, valves 40c and 40d, the gas supplier 44a, the additional gas supplier 44b, and the slits 10D.

A heater 12 that heats the wafers W in the process chamber 14 to a predetermined temperature is provided around the reaction tube 10. A temperature sensor 16 (see FIG. 7) serving as a temperature detector is installed in the reaction tube 10. The degree of energization to the heater 12 is regulated based on temperature information detected by the temperature sensor 16, so that the temperature inside the process chamber 14 is controlled to be a desired temperature distribution. The temperature sensor 16 is provided along an outer wall of the reaction tube 10. In addition, an exhaust pipe 46 is attached to the reaction tube 10 to communicate with an exhaust buffer chamber 10B. A vacuum pump 52 serving as a vacuum exhaust is connected to the exhaust pipe 46 via a pressure sensor 48 serving as a pressure detector that detects the pressure inside the process chamber 14 and an auto pressure controller (APC) valve 50 serving as a pressure regulator. With such a configuration, the pressure inside the process chamber 14 can be set to a processing pressure according to the corresponding processing.

A controller 100 is electrically connected to the rotator 30, the boat elevator 32, the MFCs 38a to 38d and the valves 40a to 40d of the gas supply mechanism 34, and an APC valve 50. The controller 100 controls these constituents. The controller 100 includes, for example, a microprocessor (computer) including a CPU, and is configured to control the operation of the processing apparatus 2. An input/output device 102 configured as, for example, a touch panel or the like is connected to the controller 100.

A memory section 104 serving as a recording medium is connected to the controller 100. The memory section 104 stores, in a readable manner, a control program that controls operation of the processing apparatus 2, a program (also referred to as a recipe) that causes each of the constituents of the processing apparatus 2 to execute processing in accordance with processing conditions.

The memory section 104 may be a memory 100c (a hard disk or a flash memory) incorporated in the controller 100, or may be a portable external memory 103 (a magnetic tape, a magnetic disk such as a flexible disk or a hard disk, an optical disk such as a CD or a DVD, a magneto-optical disk such as an MO, or a semiconductor memory such as a USB memory or a memory card). Alternatively, a program may be provided to the computer by using a communication means such as the Internet or a dedicated line. The program is read from the memory section 104 in accordance with an instruction or the like from the input/output device 102 as needed. Then, the controller 100 executes processing in accordance with the read recipe, so that the processing apparatus 2 executes desired processing under the control of the controller 100. Details of the controller 100 will be described later.

(Gas Supplier)

As illustrated in FIGS. 2 and 3, the gas supplier 44a is formed such that a first pipe 61 and a second pipe 62 are arranged in parallel with a slight gap formed between the first pipe 61 and the second pipe 62 and extend vertically. In addition, FIG. 3 is an external view of the gas supplier 44a in FIG. 2, where the openings 45a are oriented toward the front, revealing that the first pipe 61 and the second pipe 62 have different diameters.

As illustrated in FIGS. 2 and 3, the gas supplier 44a includes the first pipe 61 into which a gas is introduced, the second pipe 62 including the openings 45a from which the gas is released, and a bend 63 that connects the first pipe 61 and the second pipe 62. That is, the first pipe 61 extends upward from an introduction inlet 60 through which a gas is introduced into the first pipe 61, and reaches the bend 63 at the upper end. Then, the bend 63 is bent at 180°, and the second pipe 62 extends downward from the bend 63. The plurality of openings 45a with a slit shape are formed in a side surface of the second pipe 62 along the longitudinal direction. The second pipe 62 has a blind end near a portion where the first pipe 61 is bent. In other words, the gas supplier 44a in some embodiments can be configured as a so-called U-turn nozzle.

As illustrated in FIGS. 2 and 3, the inner diameter of the second pipe 62 is larger than the inner diameter of the first pipe 61, whereby the flow path cross-sectional area of the second pipe 62 is larger than the flow path cross-sectional area of the first pipe 61. With such a configuration, by reducing the inner diameter of the first pipe 61 serving as a forward pipe, the flow velocity of the gas increases and the thermal decomposition of the gas can be suppressed in the first pipe 61. Moreover, by decreasing the flow velocity of the gas in the second pipe 62 serving as a return pipe, the flow rates of the gas emitted from the openings 45a formed in the second pipe 62 can be made uniform. In addition, the first pipe 61 with a smaller flow path cross-sectional area and a smaller heat capacity can be disposed near the heater 12, so that the heating of the gas flowing inside the first pipe 61 can be further promoted. Furthermore, the openings 45a formed in the second pipe 62 are directed toward the center of the reaction tube 10.

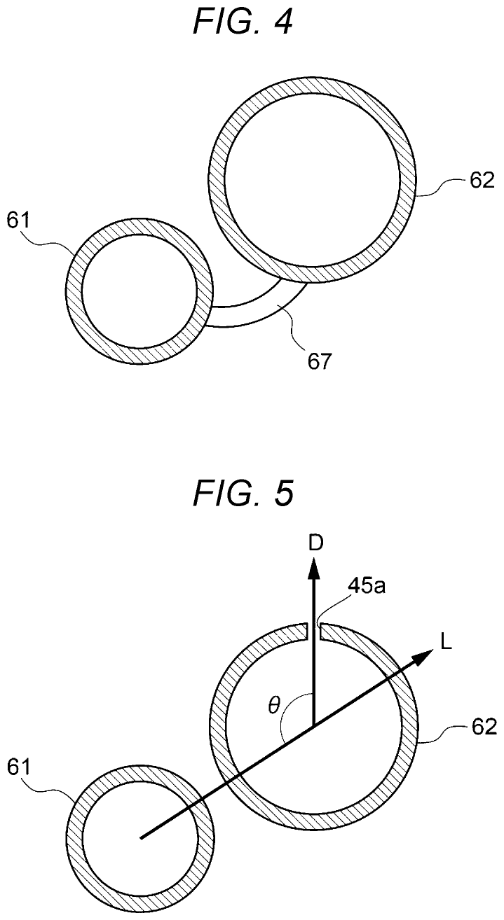

FIG. 4 (where an illustration of the opening 45a is omitted) illustrates a cross section taken along line IV-IV in FIG. 3. As illustrated in FIG. 4, the gas supplier 44a in some embodiments includes a coupler 67 that couples the first pipe 61 and the second pipe 62. Specifically, the coupler 67 with an arc shape is provided to couple outer walls of the first pipe 61 and the second pipe 62. The coupler 67 prevents the gas supplier 44a from being damaged due to thermal stress. The coupler 67 is not limited to such a form as long as the coupler 67 does not protrude from the second pipe 62, and may have a cylindrical shape, a columnar shape (with a circular cross section), or a polygonal cross-sectional shape.

In addition, FIG. 5 schematically illustrates the flow of the gas inside the gas supplier 44a. As illustrated in FIG. 5, a direction D in which a gas is released from the opening 45a is inclined with respect to a direction L from the center of the first pipe 61 toward the center of the second pipe 62. Specifically, the direction D is inclined in a direction that is not at an angle of 90° with respect to the direction L, more specifically, is inclined such that an angle θ formed by the direction D with respect to the direction L when facing the direction L is obtuse. With such a configuration, it is possible to reduce the attenuation of the gas emitting amount due to the influence of inertia at the opening 45a formed in the second pipe 62 on the upper end side.

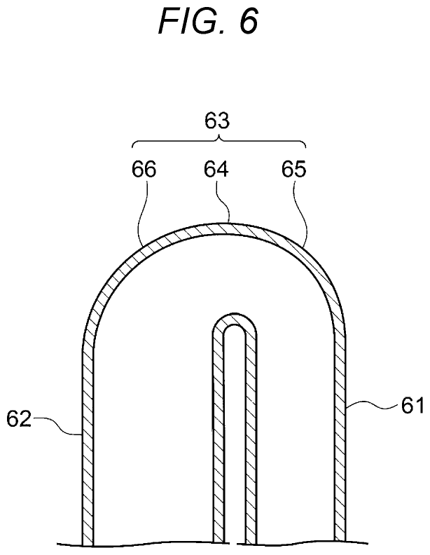

FIG. 6 is an example of a cross-sectional view of the bend 63 illustrated in FIG. 3. As illustrated in FIG. 6, the bend 63 is divided into an extension 65 with the same flow path cross-sectional area as that of the first pipe 61 and a transition 66 where the flow path cross-sectional area changes, with a vertex 64 as a boundary between the extension 65 and the transition 66, and the flow path cross-sectional area changes from the vertex 64 in the transition 66. Specifically, the flow path cross-sectional area gradually increases from the vertex 64 to the second pipe 62. With such a configuration, it is possible to release the gas from the openings 45a of the second pipe 62 serving as a return pipe without substantially changing (specifically, decreasing) the flow velocity of the gas flowing through the first pipe 61 serving as a forward pipe. Furthermore, the amounts of the gas supplied from the plurality of openings 45a can be made uniform.

As illustrated in FIG. 6, the vertex 64 of the bend 63 has the same flow path cross-sectional area as that of the first pipe 61. With such a configuration, the flow velocity of the gas to the vertex 64 can be made constant, whereby the fluctuation in the flow velocity of the gas from the first pipe 61 to the second pipe 62 can be reduced. Accordingly, it is possible to reduce the influence of the thermal decomposition or the like on the gas supplied from the openings 45a of the second pipe 62.

As illustrated in FIGS. 2 and 3, the transition 66 is provided at a position higher than the openings 45a formed in the second pipe 62. With such a configuration, the change in the flow velocity of the gas from the first pipe 61 to the second pipe 62 does not affect the flow velocity of the gas at the position of the openings 45a, and the amounts of the gas supplied from the plurality of openings 45a of the second pipe 62 can be made uniform.

As illustrated in FIG. 2, couplers 67 are provided to couple the outer walls of the first pipe 61 and the second pipe 62. With such a configuration, the couplers 67 prevent the second pipe 62 from moving away from the first pipe 61. Therefore, it is possible to prevent the stress from being generated in the bend 63 of the gas supplier 44a, particularly near the vertex 64, thus preventing the vertex 64 from being damaged. Moreover, the coupler 67 is welded while maintaining the strength. Accordingly, it is preferable to minimize the number of welded portions to reduce thermal distortion due to welding as much as possible.

As illustrated in FIG. 2, at least one coupler 67 is provided at a position higher than the lower end of the opening 45a formed in the second pipe 62. In addition, at least one coupler 67 is provided at a position lower than the opening 45a formed in the second pipe 62.

For example, in a case where the coupler 67 is provided only at the center of the second pipe 62 or near the upper end of the second pipe 62, damage caused at the vertex 64 is suppressed, but the second pipe 62 undergoes deformation due to heat below the coupler 67. Due to this deformation, flows and directions of the gas supplied from the openings 45a are not stable, so that the flows of the gas from the openings 45a cannot be made uniform. As a result, there is a concern that the quality of substrates manufactured from the wafers W may deteriorate.

However, in the embodiments, the coupler 67 is also provided on the lower end side of the second pipe 62 to couple the outer walls of the first pipe 61 and the second pipe 62. With such a configuration, in the gas supplier 44a, not only the damage caused particularly near the vertex 64 of the bend 63 due to stress can be prevented, but also deformation caused in the second pipe 62 due to heat can be prevented. As a result, the flows of the gas supplied from the openings 45a can be stabilized and the gas can be introduced in a desired direction.

As illustrated in FIG. 2, the couplers 67 are provided at a predetermined interval in the longitudinal direction of each of the first pipe 61 and the second pipe 62. That is, a plurality of couplers 67 are provided and hence, the strength of the gas supplier 44a against thermal stress is increased. As a result, the possibility that the gas supplier 44a is deformed or damaged due to heat is reduced.

Here, the cross-sectional area of the coupler 67 is formed to be smaller than the cross-sectional area of the first pipe 61. With such a configuration, the couplers 67 do not block the flows of the gas supplied from the openings 45a of the gas supplier 44a. Therefore, the flows of the gas can be made uniform. In addition, the couplers 67 can be provided so as not to protrude from the second pipe 62 in a plan view. Therefore, the gas supplier 44a can be disposed in a narrow space where the U-turn nozzle fits.

As illustrated in FIG. 5, when facing the direction L from the first pipe 61 toward the second pipe 62, the angle θ formed by the direction D, in which the gas is released from the opening 45a, with respect to the direction L is obtuse of more than 90° and less than 120°. That is, the angle θ is more than 90° and hence, the change in the direction from the direction L to the direction D is gentle. As a result, the amount of gas supplied to a wall surface of the supply buffer chamber 10A increases, and the possibility that the flow velocity and the flow rate of the gas are reduced is eliminated. In addition, the angle θ is less than 120° and hence, the gas supplier 44a can be disposed in the supply buffer chamber 10A, and the gas supplier 44a does not protrude to the process chamber 14. As a result, there is no concern that substrate processing is adversely affected.

Here, the openings 45a are formed at intermediate portions of the flow path formed inside the second pipe 62, in a direction (that is, the vertical direction) intersecting a direction in which the gas flows inside the second pipe (that is, in the drawing, the direction perpendicular to the paper surface) as illustrated in FIG. 4. In addition, each opening 45a is drawn in a slit shape in the drawing, but the opening 45a may be a hole, and a plurality of slits or holes are formed in the second pipe 62 along the longitudinal direction. With such a configuration, the flow rates of the gas supplied from the openings 45a arranged in the second pipe 62 can be made uniform in the longitudinal direction of the second pipe 62 (in other words, the vertical direction).

The processing apparatus 2 in some embodiments illustrated in FIG. 1 includes the gas supplier 44a as described above. That is, the processing apparatus 2 in some embodiments includes the gas supplier 44a including: the first pipe 61 into which a gas is introduced; the second pipe 62 including the openings 45a from which the gas is released; and the bend 63 that connects the first pipe 61 and the second pipe 62. The flow path cross-sectional area of the second pipe 62 is larger than the flow path cross-sectional area of the first pipe 61. In a plan view, the direction D in which the gas is released from the opening 45a is inclined with respect to the direction L from the center of the first pipe 61 toward the center of the second pipe 62 (see FIG. 5).

In the processing apparatus 2 according to some embodiments, the inner diameter of the second pipe 62 is larger than the inner diameter of the first pipe 61 in the gas supplier 44a, whereby the flow path cross-sectional area of the second pipe 62 is larger than the flow path cross-sectional area of the first pipe 61. With such a configuration, by reducing the inner diameter of the first pipe 61 serving as a forward pipe, the flow velocity of the gas increases and the thermal decomposition of the gas can be suppressed in the first pipe 61. Moreover, by decreasing the flow velocity of the gas in the second pipe 62 serving as a return pipe, the flow rates of the gas emitted from the openings 45a formed in the second pipe 62 can be made uniform.

Furthermore, the openings 45a formed in the second pipe 62 are directed toward the center of the reaction tube 10. That is, when viewed from the center direction of the reaction tube 10, the openings 45a are located in front and it appears that the second pipe 62 and the first pipe 61 partially overlap each other as illustrated in FIG. 3. As illustrated in FIG. 5, the direction D in which the gas is released from the opening 45a is inclined in a direction that is not at an angle of 90° with respect to the straight line L that connects the center of the first pipe 61 and the center of the second pipe 62. With such a configuration, in the processing apparatus 2 in some embodiments, it is possible to reduce the attenuation of the gas emitting amount due to the influence of inertia at the opening 45a formed in the second pipe 62 on the upper end side.

In the processing apparatus 2 in some embodiments, as schematically illustrated in a planar cross section in FIG. 7, the supply buffer chamber 10A accommodates the additional gas supplier 44b in addition to the gas supplier 44a described above, with a partition wall 10C interposed therebetween.

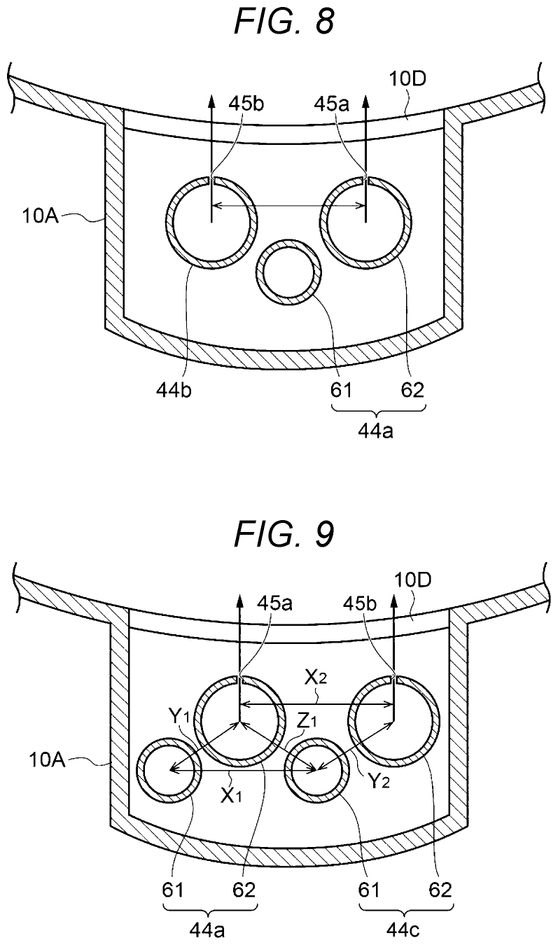

Alternatively, the supply buffer chamber 10A may be a single chamber formed without the partition wall 10C as illustrated in FIG. 8, and further accommodate the additional gas supplier 44b formed with openings 45b in the side surface thereof. The gas supplier 44a and the additional gas supplier 44b are disposed adjacent to each other in the supply buffer chamber 10A, and gases are supplied from both gas suppliers. In this case, the gas supplied from the gas supplier 44a and the gas supplied from the additional gas supplier 44b are desirably different from each other. Specifically, it is desirable that the gas supplier 44a is configured to supply a source gas, and the additional gas supplier 44b is configured to supply a reactant gas. Furthermore, the opening 45a of the gas supplier 44a may be formed in a slit shape, and the opening 45b of the additional gas supplier 44b may be formed in a hole shape.

Here, the additional gas supplier 44b has the same length in the vertical direction as that of the gas supplier 44a, and is configured as a so-called straight nozzle that extends straight from the lower end to the upper end, instead of the U-turn nozzle like the gas supplier 44a. In addition, on a side of the additional gas supplier 44b facing the center of the reaction tube 10, a plurality of openings 45b with a hole shape are formed along the longitudinal direction substantially coinciding with the range in which the openings 45a with a slit shape are formed in the gas supplier 44a.

the above configuration, the distance between the opening 45a of the gas supplier 44a and the opening 45b of the additional gas supplier 44b can be reduced. This produces an effect of suppressing return flows of the gases supplied from the opening 45a and the opening 45b. Accordingly, the gases supplied from the opening 45a and the opening 45b uniformly flow on the surface of the wafer W without generating return flows on the wafer W, so that uniformity of the thickness of the film on the surface of the wafer W is expected. In addition, the process performance in the substrate processing can be secured, and the installation space for the gas supplier 44a and the additional gas supplier 44b can be made extremely small. For example, the gas supplier 44a as a U-turn nozzle and the additional gas supplier 44b as a straight nozzle can be installed close to each other in the supply buffer chamber 10A, so that space saving can be expected.

Alternatively, as illustrated in FIG. 9, the processing apparatus 2 in some embodiments may further include a second gas supplier 44c with the same configuration as that of the gas supplier 44a in the supply buffer chamber 10A that is a single chamber formed without the partition wall 10C. Here, the gas supplier 44a and the second gas supplier 44c may be disposed adjacent to each other, and gases may be supplied from both of the gas suppliers. In addition, the gas supplier 44a and the second gas supplier 44c may be disposed such that a distance X₁ between the centers of the first pipes 61 and 61 is equal to a distance X₂ between the centers of the second pipes 62 and 62. Moreover, in a plan view, at least one of a distance Y₁ between the center of the first pipe 61 and the center of the second pipe 62 in the gas supplier 44a and a distance Y₂ between the center of the first pipe 61 and the center of the second pipe 62 in the second gas supplier 44c is desirably shorter than the distance X₁ between the center of the first pipe 61 of the gas supplier 44a and the center of the first pipe 61 of the second gas supplier 44c or the distance X₂ between the center of the second pipe 62 of the gas supplier 44a and the center of the second pipe 62 of the second gas supplier 44c. In addition, in a plan view, the distance Y₁ between the center of the first pipe 61 and the center of the second pipe 62 in the gas supplier 44a is desirably equal to a distance Z₁ between the center of the second pipe 62 of the gas supplier 44a and the center of the first pipe 61 of the second gas supplier 44c.

With the above configuration, the distance between the opening 45a of the gas supplier 44a and the opening 45b of the second gas supplier 44c can be reduced. This produces an effect of suppressing return flows of the gases supplied from the opening 45a and the opening 45b. Accordingly, the gases supplied from the opening 45a and the opening 45b uniformly flow on the surface of the wafer W without generating return flows on the wafer W, so that uniformity of the thickness of the film on the surface of the wafer W is expected. In addition, the process performance in the substrate processing can be secured, and the installation space for the gas supplier 44a and the second gas supplier 44c can be made extremely small. For example, the gas supplier 44a and the second gas supplier 44c serving as two U-turn nozzles can be installed close to each other in the supply buffer chamber 10A, so that space saving can be expected.

(Controller)

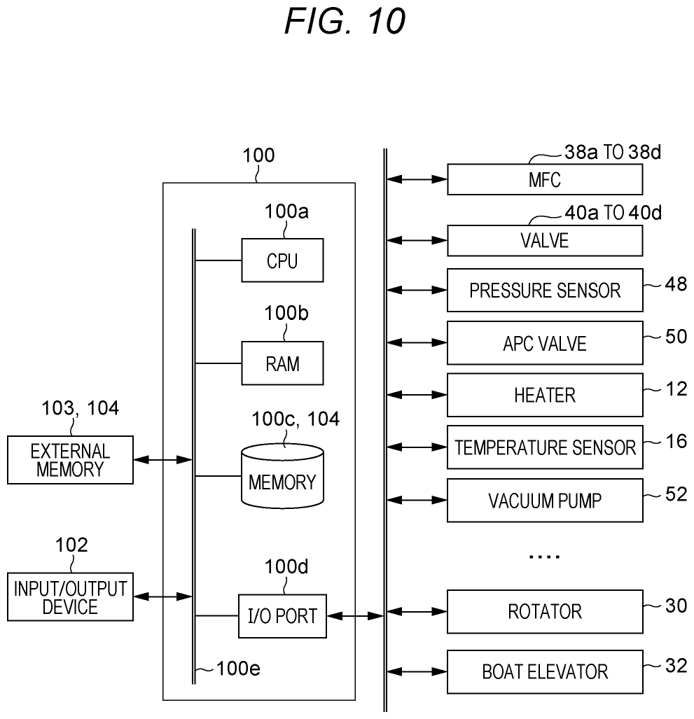

As illustrated in FIG. 10, the controller 100 serving as a control means is configured as a computer including a central processing unit (CPU) 100a, a random access memory (RAM) 100b, the memory 100c, and an I/O port 100d. The RAM 100b, the memory 100c, and the I/O port 100d are configured to be capable of exchanging data with the CPU 100a via an internal bus 100e. The input/output device 102 configured as, for example, a touch panel or the like is connected to the controller 100.

The memory 100c includes, for example, a flash memory, a hard disk drive (HDD), or the like. A control program that controls the operation of a substrate processing apparatus, an etching recipe or a process recipe in which procedures, conditions, and the like of nozzle etching processing and film forming processing described later are described, and the like are readably stored in the memory 100c. The etching recipe or the process recipe is combined to function as a program that causes the controller 100 to perform each procedure in the substrate processing process, described later, to obtain a predetermined result. Hereinafter, the process recipe, the control program, and the like are also collectively and simply referred to as a program. In addition, the etching recipe and the process recipe are each simply referred to as a recipe. When the term “program” is used in the present specification, it may indicate a case of including the recipe, a case of including the control program, or a case of including both the recipe and the control program. The RAM 100b is configured as a memory area (work area) in which the program, data, and the like read by the CPU 100a are temporarily stored.

The I/O port 100d is connected to the MFCs 38a to 38d, the valves 40a to 40d, the pressure sensor 48, the APC valve 50, the vacuum pump 52, the heater 12, the temperature sensor 16, the rotator 30, the boat elevator 32, and the like described above.

The CPU 100a is configured to read the control program from the memory 100c and execute the control program, and to read the recipe from the memory 100c in response to an input or the like of an operation command from the input/output device 102. The CPU 100a is configured to control, in accordance with the content of the read recipe, flow rate regulating operations of various gases by the MFCs 38a to 38d, opening/closing operations of the valves 40a to 40d, an opening/closing operation of the APC valve 50, a pressure regulating operation by the APC valve 50 based on the pressure sensor 48, start and stop of the vacuum pump 52, a temperature regulating operation of the heater 12 based on the temperature sensor 16, a rotating operation and a rotation speed regulating operation of the boat 26 by the rotator 30, a raising/lowering operation of the boat 26 by the boat elevator 32, and the like.

The controller 100 can be configured by installing the above-described program stored in an external memory (for example, a magnetic tape, a magnetic disk such as a flexible disk or a hard disk, an optical disk such as a CD or a DVD, a magneto-optical disk such as an MO, or a semiconductor memory such as a USB memory or a memory card) 103 in a computer. The memory 100c and the external memory 103 are included in the memory section 104 illustrated in FIG. 1 and configured as a computer-readable recording medium. Hereinafter, the memory 100c and the external memory 103 are also collectively and simply referred to as a recording medium. When the term “recording medium” is used in the present specification, it may indicate a case of including the memory 100c, a case of including the external memory 103, or a case of including both the memory 100c and the external memory 103. Furthermore, the program may be provided to the computer by using a communication means such as the Internet or a dedicated line without using the external memory 103.

Next, an example of a method of manufacturing a semiconductor device will be described where processing in which a film is formed on a substrate (that is, film forming processing) is performed by using the above-described processing apparatus 2. Here, an example will be described in which a film is formed on the wafer W by supplying a source gas and a reactant gas to the wafer W. Furthermore, in the following description, the controller 100 controls the operation of each constituent included in the processing apparatus 2.

(Wafer Charge and Boat Load)

When a plurality of wafers W are charged on the boat 26 (wafer charge), the boat 26 is loaded into the process chamber 14 by the boat elevator 32 (boat load), and the lower end opening of the reaction tube 10 is brought into a hermetically sealed state by the lid 22.

(Pressure Regulation and Temperature Regulation)

The inside of the process chamber 14 is vacuum-exhausted (decompressed) by the vacuum pump 52 to obtain a predetermined pressure (degree of vacuum). The pressure sensor 48 measures the pressure inside the process chamber 14, and then the APC valve 50 is feedback-controlled based on the measured pressure information. In addition, the wafers W in the process chamber 14 are heated by the heater 12 to obtain a predetermined temperature. At this time, the degree of energization to the heater 12 is feedback-controlled based on the temperature information detected by the temperature sensor 16 to obtain a predetermined temperature distribution inside the process chamber 14. In addition, the rotator 30 starts to rotate the boat 26 and wafers W.

(Film Forming Processing)

[Source Gas Supply Process]

When the temperature inside the process chamber 14 is stabilized at a preset processing temperature, a source gas is supplied to the wafers W in the process chamber 14. The source gas is controlled by the MFC 38a to obtain a desired flow rate, and is supplied into the process chamber 14 through the gas supply pipe 36a, the gas supplier 44a, and the slits 10D.

[Source Gas Exhaust Process]

Next, the supply of the source gas is stopped, and the inside of the process chamber 14 is vacuum-exhausted by the vacuum pump 52. At this point, an inert gas may be supplied into the process chamber 14 from the inert gas supply system (inert gas purge).

[Reactant Gas Supply Process]

Next, a reactant gas is supplied to the wafers W in the process chamber 14. The reactant gas is controlled by the MFC 38b to obtain a desired flow rate, and is supplied into the process chamber 14 through the gas supply pipe 36b, the additional gas supplier 44b, and the slits 10D.

[Reactant Gas Exhaust Process]

Next, the supply of the reactant gas is stopped, and the inside of the process chamber 14 is vacuum-exhausted by the vacuum pump 52. At this point, the inert gas may be supplied into the process chamber 14 from the inert gas supply system (inert gas purge).

A film with a predetermined composition and a predetermined film thickness can be formed on each wafer W by performing a cycle including the above-described four processes a predetermined number of times (one or more times).

(Boat Unload and Wafer Discharge)

After forming the film with a predetermined film thickness, the inert gas is supplied from the inert gas supply system, the atmosphere inside the process chamber 14 is replaced with the inert gas, and the pressure inside the process chamber 14 is restored to the normal pressure. Thereafter, the lid 22 is lowered by the boat elevator 32, and the boat 26 is unloaded from the reaction tube 10 (boat unload). Thereafter, the processed wafers W are taken out from the boat 26 (wafer discharge).

The processing conditions at the time of forming a film on each wafer W are exemplified as follows. Each of the following numerical ranges includes a lower limit value and an upper limit value.
Processing temperature (wafer temperature): 300° C. to 700° C.
Processing pressure (pressure inside process chamber): 1 Pa to 4000 Pa
Source gas: 100 sccm to 10000 sccm
reactant gas: 100 sccm to 10000 sccm
Inert gas: 100 sccm to 10000 sccm

The film forming processing can be properly progressed by setting each of the processing conditions to a value within each of the above ranges.

Furthermore, the processing apparatus 2 in some embodiments is applicable not only to the apparatus for manufacturing a semiconductor but also to an apparatus for processing a glass substrate such as an LCD apparatus. In addition, the processing apparatus 2 in some embodiments is also applicable to an apparatus that performs processing such as annealing, oxidizing, nitriding, or diffusion processing. Moreover, the above-described film forming processing includes, for example, CVD, PVD, processing of forming an oxide film or a nitride film or both, or processing of forming a film containing metal.

### Example

As an example, the operation and effects obtained by the processing apparatus 2 including the gas supplier 44a in some embodiments in a case where a source gas was caused to flow inside were verified. Alternatively, as a comparative example, a similar verification was performed on a processing apparatus equipped with a conventional U-turn nozzle. In the conventional U-turn nozzle, the inner diameter of the forward path is equal to that of the return path, and the direction from the center of the forward path toward the center of the return path is orthogonal to the direction in which a gas is released from an opening. Furthermore, in each graph referred to below, a solid line represents the example, and a broken line represents a comparative example.

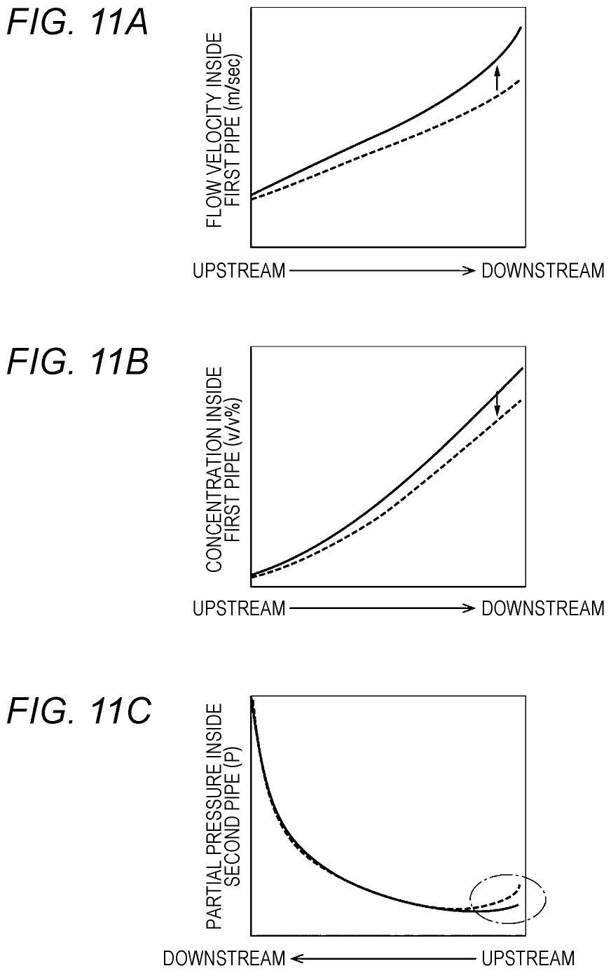

FIG. 11A is a graph illustrating the flow velocity of the source gas in the first pipe 61 of the gas supplier 44a. In the graph, the vertical axis represents the flow velocity (m/sec) inside the first pipe 61, and the horizontal axis represents the height of the measurement point. That is, the graph indicates that the source gas rises in the first pipe 61 from the upstream side, which is the left side, to the downstream side, which is the right side, in the horizontal axis of the graph. In the gas supplier 44a in some embodiments, the inner diameter of the first pipe 61 that is the forward path of a U-turn nozzle is smaller than the inner diameter of the conventional U-turn nozzle. Accordingly, the flow velocity of the source gas increased throughout the entire region from the upstream side to the downstream side, and the increase in the flow velocity on the downstream side was particularly remarkable.

FIG. 11B is a graph illustrating the concentration of a pyrolysis gas that is a by-product generated by thermal decomposition of the source gas in the first pipe 61 of the gas supplier 44a. In the graph, the vertical axis represents the concentration (v/v %) of the pyrolysis gas with respect to the entire gas in the first pipe 61, and the horizontal axis represents the height of the measurement point. That is, the graph indicates that the source gas rises in the first pipe 61 from the upstream side, which is the left side, to the downstream side, which is the right side, in the horizontal axis of the graph. Along with the increase in the flow velocity of the source gas in the first pipe 61 illustrated in the graph in FIG. 11A, particularly in the downstream region where the flow velocity remarkably increased, the thermal decomposition of the source gas was suppressed as compared with the conventional U-turn nozzle, resulting in a decrease in the concentration of the pyrolysis gas.

FIG. 11C is a graph illustrating a partial pressure of the pyrolysis gas that is a by-product generated by the thermal decomposition of the source gas in the second pipe 62 of the gas supplier 44a. In the graph, the vertical axis represents the partial pressure (P) of the pyrolysis gas with respect to the entire gas in the second pipe 62, and the horizontal axis represents the height of the measurement point. That is, the graph indicates that the source gas descends in the second pipe 62 from the upstream side, which is the right side, to the downstream side, which is the left side, in the horizontal axis of the graph. Along with the reduction in the concentration of the pyrolysis gas on the downstream side in the first pipe 61 illustrated in the graph in FIG. 11B, in the upstream region (see the area surrounded by a chain line) in the second pipe 62 immediately after the coupler 67, a decrease in the partial pressure of the pyrolysis gas was observed as compared with the conventional U-turn nozzle.

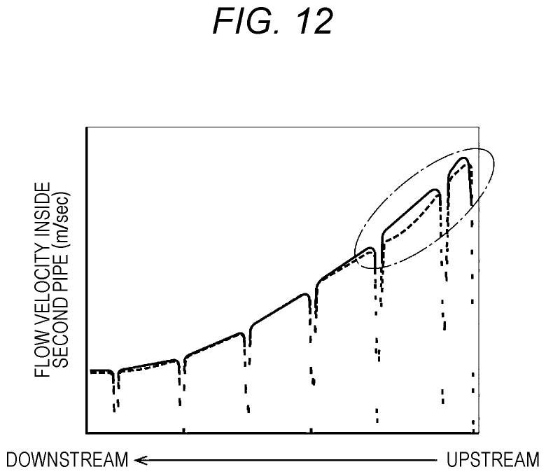

FIG. 12 is a graph illustrating the flow velocity of a gas in the openings 45a of the second pipe 62 of the gas supplier 44a. In the graph, the vertical axis represents the flow velocity (m/sec) of the source gas in the second pipe 62, and the horizontal axis represents the height of the measurement point. That is, the graph indicates that the source gas descends in the second pipe 62 from the upstream side, which is the right side, to the downstream side, which is the left side, in the horizontal axis of the graph. Furthermore, the curve of the graph is periodically broken at a portion where the opening 45a is interrupted to secure the strength. As illustrated in the graph, it was observed that the decrease in the flow velocity in the upstream region (see the area surrounded by a chain line) observed in the conventional U-turn nozzle did not occur in the example. This is related to the angle formed by the direction of a gas exiting from the opening when the gas is directed in a direction from the forward path toward the return path of the U-turn nozzle. That is, in a case where the angle is a right angle as in the conventional U-turn nozzle, it is considered that a flow avoiding the opening is formed due to the influence of inertia in the upstream region of the return path immediately after the U-turn, and the outflow amount of the gas from the opening is slightly attenuated. On the other hand, in the example, it is considered that since the angle is obtuse as compared with the conventional U-turn nozzle (see FIG. 5), the attenuation of the outflow amount of the gas due to the influence of inertia of the flow of the gas was reduced.

According to the present disclosure, space saving of a gas supplier can be achieved while securing characteristics of a gas supplied from openings.

What is claimed is:

1. A gas supplier, comprising a first pipe into which a gas is introduced, and a second pipe including an opening from which the gas is released, wherein
a flow path cross-sectional area of the second pipe is larger than a flow path cross-sectional area of the first pipe, and
a direction in which the gas is released from the opening is inclined with respect to a direction from a center of the first pipe toward a center of the second pipe in a plan view.

2. The gas supplier according to claim 1, further comprising a bend that connects the first pipe and the second pipe, wherein
the bend is divided into an extension with a same flow path cross-sectional area as the flow path cross-sectional area of the first pipe and a transition where the flow path cross-sectional area changes, with a vertex as a boundary between the extension and the transition, and
the flow path cross-sectional area changes from the vertex in the transition.

3. The gas supplier according to claim 2, wherein the vertex of the bend includes the same flow path cross-sectional area as the flow path cross-sectional area of the first pipe.

4. The gas supplier according to claim 2, wherein the transition is provided at a position higher than the opening formed in the second pipe.

5. The gas supplier according to claim 1, further comprising a coupler that couples the first pipe and the second pipe.

6. The gas supplier according to claim 5, wherein the coupler includes at least one coupler provided near a lower end of the opening formed in the second pipe.

7. The gas supplier according to claim 5, wherein the coupler includes at least one coupler provided at a position lower than the opening formed in the second pipe.

8. The gas supplier according to claim 5, wherein the coupler includes a plurality of couplers provided at a predetermined interval in a longitudinal direction of each of the first pipe and the second pipe.

9. The gas supplier according to claim 5, wherein a cross-sectional area of the coupler is formed to be smaller than a cross-sectional area of the first pipe.

10. The gas supplier according to claim 1, wherein the opening is formed at an intermediate portion of a flow path formed inside the second pipe, in a direction intersecting a direction in which the gas flows inside the second pipe.

11. The gas supplier according to claim 1, wherein
the opening is a slit or a hole, and
the slit or the hole includes a plurality of slits or a plurality of holes formed along a longitudinal direction of the second pipe.

12. A processing apparatus, comprising a gas supplier that includes a first pipe into which a gas is introduced and a second pipe including an opening from which the gas is released, wherein
a flow path cross-sectional area of the second pipe is larger than a flow path cross-sectional area of the first pipe, and
a direction in which the gas is released from the opening is inclined with respect to a direction from a center of the first pipe toward a center of the second pipe in a plan view.

13. The processing apparatus according to claim 12, further comprising a second gas supplier with a same configuration as a configuration of the gas supplier, wherein
the gas supplier and the second gas supplier are disposed adjacent to each other, and the gas is supplied from both the gas supplier and the second gas supplier.

14. The processing apparatus according to claim 13, wherein in a plan view, at least one of a distance between the center of the first pipe and the center of the second pipe in the gas supplier and a distance between a center of a first pipe and a center of a second pipe in the second gas supplier is shorter than a distance between the center of the first pipe of the gas supplier and the center of the first pipe of the second gas supplier or a distance between the center of the second pipe of the gas supplier and the center of the second pipe of the second gas supplier.

15. The processing apparatus according to claim 13, wherein in a plan view, a distance between the center of the first pipe and the center of the second pipe in the gas supplier is equal to a distance between the center of the second pipe of the gas supplier and a center of a first pipe of the second gas supplier.

16. The processing apparatus according to claim 12, further comprising an additional gas supplier formed with an opening in a side surface, wherein
the gas supplier and the additional gas supplier are disposed to each other, and the gas is supplied from both the gas supplier and the additional gas supplier.

17. The processing apparatus according to claim 12, wherein a gas supplied from the gas supplier and a gas supplied from the additional gas supplier are different from each other.

18. The processing apparatus according to claim 16, wherein
the gas supplier is configured to supply a source gas, and the additional gas supplier is configured to supply a reactant gas.

19. The processing apparatus according to claim 16, wherein
the opening of the gas supplier is formed in a slit shape, and
the opening of the additional gas supplier is formed in a hole shape.

20. A method of manufacturing a semiconductor device, the method comprising supplying a gas to process an object to be processed by using a gas supplier that includes:
a first pipe into which the gas is introduced and a second pipe including an opening from which the gas is released, wherein
a flow path cross-sectional area of the second pipe is larger than a flow path cross-sectional area of the first pipe, and
a direction in which the gas is released from the opening is inclined with respect to a direction from a center of the first pipe toward a center of the second pipe in a plan view.
